(19) United States
(12) Patent Application Publication
(10) Pub. No.: US 2020/0194076 A1
(43) Pub. Date: Jun. 18, 2020

(54) NONVOLATILE MEMORY AND PROGRAMMING METHOD THEREOF

(71) Applicants: GigaDevice Semiconductor (Beijing) Inc., Beijing (CN); GigaDevice Semiconductor (Shanghai) Inc., Shanghai (CN)

(72) Inventors: Minyi Chen, Beijing (CN); Chunhui Chen, Beijing (CN); Xiao Luo, Beijing (CN)

(73) Assignees: GigaDevice Semiconductor (Beijing) Inc., Beijing (CN); GigaDevice Semiconductor (Shanghai) Inc., Shanghai (CN)

(21) Appl. No.: 16/236,610

(22) Filed: Dec. 30, 2018

(30) Foreign Application Priority Data
Dec. 14, 2018 (CN) 201811536494.X

(51) Int. Cl. G11C 16/12; G11C 16/04

(52) U.S. Cl. CPC G11C 16/12; H01L 27/11524; G11C 16/0483

(57) ABSTRACT

Disclosed are a nonvolatile memory and a programming method to reduce the tunnel oxide stress. The programming method includes: applying one program voltage pulse to a word line connected to a target memory cell, and then applying one or more incremental step voltage pulses to the word line connected to the target memory cell. The one program voltage pulse linearly increases from a first voltage level to a second voltage level, or the one program voltage pulse is in a staircase shape. The one or more incremental step voltage pulses start from an initial voltage level and have a predetermined step size.

### CROSS-REFERENCE TO RELATED APPLICATIONS

This application claims priority to a Chinese patent application No. 201811536494.X filed on Dec. 14, 2018, the disclosure of which is incorporated herein by reference in its entirety.

### TECHNICAL FIELD

The present disclosure relates generally to the nonvolatile memory filed, particularly to a nonvolatile memory and a programming method of the nonvolatile memory.

### BACKGROUND

Nonvolatile memory is widely used for data storage applications, and becomes an indispensable component of modern electronic systems, such as personal computers, cellular phones, digital cameras, automotive systems, global positioning systems and the like. Data stored in the nonvolatile memory is not lost when the power supply is removed.

Flash memory is a representative nonvolatile memory device, and is divided into an NOR flash memory and an NAND flash memory in accordance with a configuration of a memory cell array. In the NOR flash memory, each of memory cells is connected independently to a bit line and a word line, and so the NOR flash memory has excellent random access time. Whereas, in the NAND flash memory, only one contact is required for one cell string because memory cells are connected in series, and so the NAND flash memory has excellent characteristics for integration. Accordingly, the NAND flash memory has been generally employed in high density flash memory.

Operations on flash memory typically include programming, erasing and reading. For the NAND flash memory, the programming operation is carried out by applying a programming voltage to the word line to which control gates of the memory cells of a selected page are connected. Incremental Step Pulse Programming (ISPP) is one programming scheme useful in maintaining a tight cell threshold voltage distribution for higher data reliability. In ISPP, the programming voltage applied to the control gates of the selected page to be programmed is incrementally increased until the threshold voltage reaches a desired level. In particular, the programming voltage is applied at a first level, after which the threshold voltage of the memory cell to be programmed is checked (read) to determine whether the memory cell is properly programmed. If the verification fails, the programming voltage is increased, followed by another round of verification. The programming voltage may be incrementally increased in this manner until the desired threshold voltage is achieved.

However, ISPP leads to a large page programming stress and increases the programing cycles.

### SUMMARY

The following is a summary of a subject matter described herein in detail.

According to a first aspect of the present disclosure, a nonvolatile memory is provided. The nonvolatile memory includes: word lines; bit lines; a memory cell array addressed through the word lines and bit lines; and a controller. The controller is configured to: apply one program voltage pulse to the word line connected to a target memory cell in the memory cell array, and then apply one or more incremental step voltage pulses to the word line connected to the target memory cell in the memory cell array. The one program voltage pulse increases from a first voltage level to a second voltage level.

In an exemplary embodiment, the one or more incremental step voltage pulses start from an initial voltage level and have a predetermined step size, and the initial voltage level is equal to the second voltage level.

In an exemplary embodiment, the one or more incremental step voltage pulses start from an initial voltage level and have a predetermined step size, and the initial voltage level is less than the second voltage level.

In an exemplary embodiment, the one or more incremental step voltage pulses start from an initial voltage level and have a predetermined step size, and the initial voltage level is equal to a sum of the second voltage level and the predetermined step size.

In an exemplary embodiment, the one or more incremental step voltage pulses start from an initial voltage level and have a predetermined step size, and the initial voltage level is equal to a sum of the second voltage level and a predetermined value, wherein the predetermined value is not equal to the predetermined step size.

In an exemplary embodiment, the one program voltage pulse linearly increases from the first voltage level to the second voltage level.

In an exemplary embodiment, the one program voltage pulse is in a staircase shape.

In an exemplary embodiment, a time duration of each stair of the one program voltage pulse is less than or equal to 0.8 us.

In an exemplary embodiment, a step size of the one program voltage pulse is less than or equal to 0.7 V.

In an exemplary embodiment, time durations of stairs of the one program voltage pulse are consecutive in time.

In an exemplary embodiment, the nonvolatile memory is a NAND flash memory.

According to a second aspect of the present disclosure, a computing system is provided. The computing system includes the nonvolatile memory disclosed in any embodiment in the first aspect.

According to a third aspect of the present disclosure, a programming method of a nonvolatile memory is provided. The programming method includes: applying one program voltage pulse to a word line connected to a target memory cell, and then applying one or more incremental step voltage pulses to the word line connected to the target memory cell. The one program voltage pulse increases from a first voltage level to a second voltage level.

In an exemplary embodiment, the one or more incremental step voltage pulses start from an initial voltage level and have a predetermined step size, and the initial voltage level is equal to the second voltage level.

In an exemplary embodiment, the one or more incremental step voltage pulses start from an initial voltage level and have a predetermined step size, and the initial voltage level is less than the second voltage level.

In an exemplary embodiment, the one or more incremental step voltage pulses start from an initial voltage level and have a predetermined step size, and the initial voltage level is equal to a sum of the second voltage level and the predetermined step size.

In an exemplary embodiment, the one or more incremental step voltage pulses start from an initial voltage level and have a predetermined step size, and the initial voltage level is equal to a sum of the second voltage level and a predetermined value, wherein the predetermined value is not equal to the predetermined step size.

In an exemplary embodiment, the one program voltage pulse linearly increases from the first voltage level to the second voltage level.

In an exemplary embodiment, the one program voltage pulse is in a staircase shape.

In an exemplary embodiment, time durations of stairs of the one program voltage pulse are consecutive in time

With the nonvolatile memory and the programming method, the tunnel oxide stress is reduced.

### BRIEF DESCRIPTION OF DRAWINGS

The accompanying drawings are used for providing further understanding of the present disclosure and constitute a part of this specification. Elements and/or components in the figures are not necessarily drawn to scale.

FIG. 1 is a simplified block diagram of a flash memory according to an embodiment of the present disclosure.

FIG. 2 is a schematic diagram illustrating an exemplary configuration of a flash memory block.

FIG. 3 is a schematic block diagram of a floating-gate transistor.

FIG. 4 is a schematic diagram illustrating voltages applied to word lines and bit lines when a programming operation is performed.

FIG. 5 is a flowchart of a programming method for a flash memory.

FIG. 6 is a schematic diagram illustrating pulses of a programming voltage according to the programming method.

FIG. 7 is a schematic diagram illustrating a staircase-voltage pulse of the programming voltage.

FIG. 8 is a schematic diagram illustrating pulses of another programming voltage according to the programming method.

FIG. 9 is a schematic diagram illustrating pulses of yet another programming voltage according to the programming method.

FIG. 10 is a flowchart of another programming method.

FIG. 11 is a schematic diagram illustrating a programming voltage according to yet another programming method.

### DETAILED DESCRIPTION

The invention is described more fully hereinafter with reference to the accompanying drawings, in which embodiments of the invention are shown. This invention may be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes or configurations of elements may be idealized or exaggerated for clarity.

It will be understood that when an element is referred to as being “connected to” or “coupled to” another element, it may be directly connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third etc. may be used herein to describe various elements, components and/or sections, these elements, components and/or sections should not be limited by these terms. These terms are only used to distinguish one element, component, or section from another element, region or section. Thus, a first element, component or section discussed below could be termed a second element, component or section without departing from the teachings of the present invention.

The terminology used herein is for the purpose of describing particular embodiments only and is not intended to be limiting of the invention. As used herein, the singular forms “a”, “an” and “the” are intended to include the plural forms as well unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

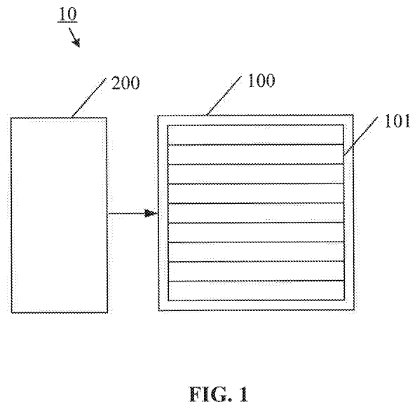

FIG. 1 is a simplified block diagram of an exemplary flash memory 10 suitable for implementing aspects of the present disclosure. The flash memory 10 shown in FIG. 1 has been simplified to focus on particular elements to improve understanding the present disclosure. As shown in FIG. 1, the flash memory 10 includes a flash memory cell array 100 and a controller 200. Typically, the controller 200 is an application specific integrated circuit (ASIC) and includes a row decode circuit, a column decode circuit, an I/O circuit, an address circuit, a data register, and a charge pump. The flash memory support three primary operations: erasing, programming, and reading.

The controller 200 may be connected to a host (not shown). The controller 200 is configured to accept data to be stored into the flash memory cell array 100 from the host, and to output data retrieved from the flash memory cell array 100 to the host.

In an exemplary embodiment, the flash memory 10 shown in FIG. 1 is a NAND flash memory. The flash memory cell array 100 may be a two-dimensional flash memory cell array, or a three-dimensional stack of flash memory cells, such as 3D NAND flash memory. The flash memory cell array 100 includes a plurality of individually erasable blocks 101. Each block 101 may include a plurality of pages 110 of flash memory cells 106. In this embodiment, the flash memory cell array 100 is organized as a two-dimensional array of memory cells arranged in rows and columns and addressable by word lines and bit lines.

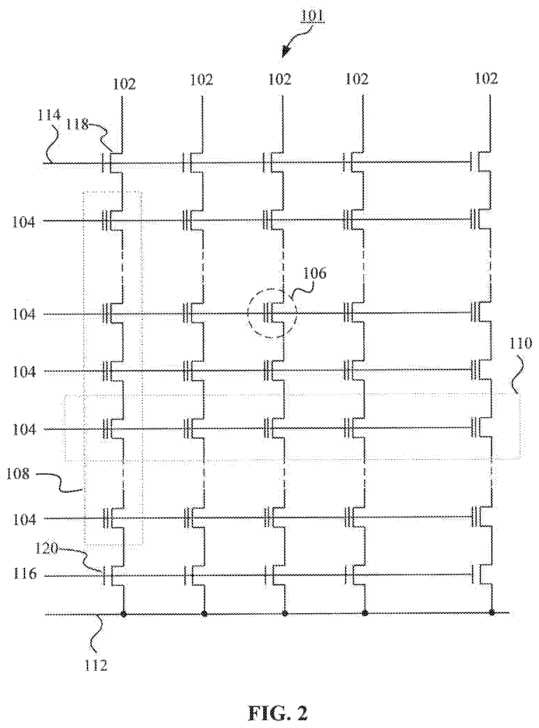

FIG. 2 shows an exemplary configuration of the flash memory block 101 of the NAND flash memory. The flash memory cells 106 are be arranged in rows and columns. The flash memory cells 106 in the column direction are connected in series to constitute a string 108. Specifically, the flash memory cells 106 in a same string are daisy-chained by their sources and drains. Each string 108 is connected to a bit line 102 via a first select switch 118. Data can be read via the bit line 102. The first select switch 118 controls the connection and disconnection between the string 108 and the bit line 102. The first select switch 118 is controlled by a first control signal line 114. Each string 108 is further connected to a common source line 112 via a second select switch 120. The second select switch 120 is controlled by a second control signal line 116. The flash memory cells 106 in the row direction shares a same word line 104, and constitute one page 110. In other words, control gates of the flash memory cells 106 in a same page are all connected to a same word line 104. As an example for better understanding, a 2G bits NAND flash memory cell array is ordered into 2048 blocks, with 64 pages per block, and each page contains 2048 flash memory cells.

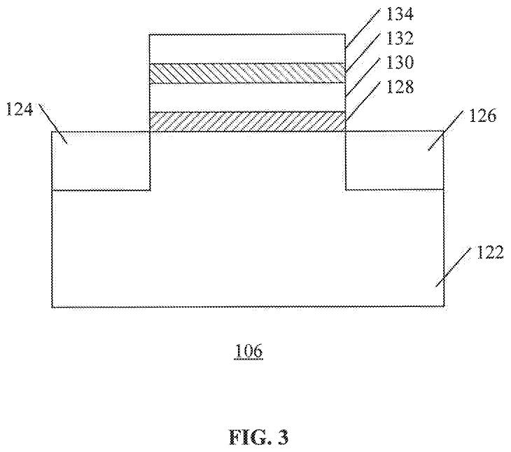

The flash memory cell can be implemented by a field-effect transistor having a charge trapping layer sandwiched between two oxide layers. The charge trapping layer may be a floating gate or a charge trapping dielectric layer. The flash memory cell 106 is illustrated below by taking the floating-gate transistor as an example. FIG. 3 is a schematic block diagram of a floating-gate transistor 106. As shown in FIG. 3, the floating-gate transistor 106 includes a well region 122 (for example a p-well region 122), a source 124, a drain 126, a tunnel oxide layer 128, a floating gate 130, a blocking oxide layer 132 and a control gate 134. The floating gate 130 may be a heavily doped poly silicon. The tunnel oxide layer 128 may be made of SiO₂ or high-k dielectrics such as Al₂O₃, HfO₂, and the like. The control gate 134 is connected to the word line 104. The drain 126 is connected to the bit line 102.

Typically, the storage state of the floating-gate transistor 106 may be read by sensing a conduction current across the source and drain when a reference voltage (reading voltage) is applied to the control gate.

Programming of the floating-gate transistor 106 is typically achieved by applying a relatively large programming voltage (for example, 17 volts −20 volts) to the control gate 134. The programming voltage and another voltage between the drain 126 and the source 124 cause the formation of an inversion-layer channel of electrons at the face of the p well region 122, between the source 124 and the drain 126. The drain-to-source voltage accelerates these electrons through the inversion-layer channel to the drain 126 where they acquire sufficiently large kinetic energy and are typically referred to as “hot” electrons. The programming voltage applied on the control gate 134 also establishes an electrical field in the tunnel oxide layer 128 that separates the floating gate 130 from the channel region. This electric field attracts the hot electrons and accelerates them toward the floating gate 130, by a process known as Fowler-Nordheim (FN) tunneling. The floating gate 130 then accumulates and traps the accumulated charge.

The accumulation of a large quantity of trapped charges (electrons) on the floating gate 130 will cause the effective threshold voltage of the floating-gate transistor 106 to increase. If this increase is sufficiently large, the floating-gate transistor 106 will remain in a nonconductive “off” state when a predetermined “read” voltage is applied to the control gate 134 during a read operation. In this state, known as the programmed state, the floating-gate transistor 106 may be referred to as storing a logic “0.” If the floating-gate transistor 106 is in a conductive “on” state when a predetermined “read” voltage is applied to the control gate 134 during a read operation, the floating-gate transistor 106 may be referred to as storing a logic “1”. In an alternative embodiment, each floating-gate transistor 106 can store multiple logic values.

Typically, for the flash memory, an erasing operation is necessary before the programming operation. That is, for the NAND flash memory, the block 101 to which the selected page belongs is firstly erased, and then the programming voltage is applied to the word line of the selected page.

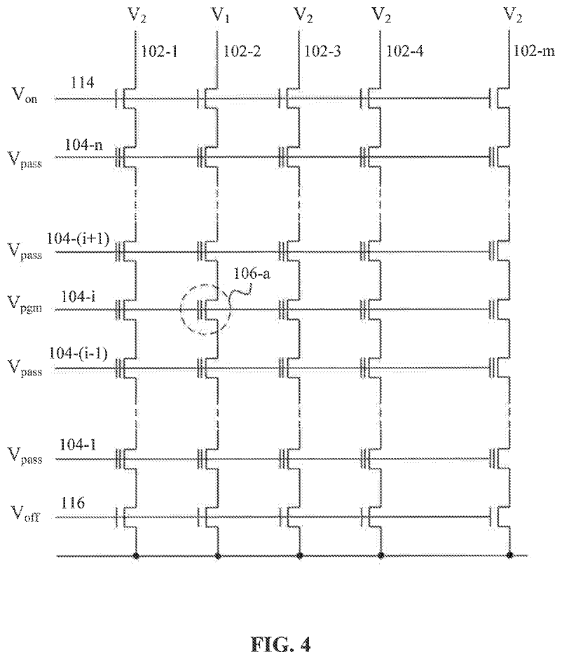

FIG. 4 is a schematic diagram illustrating voltages applied to word lines and bit lines when a programming operation is performed. As shown in FIG. 4, the page corresponding to the word line 104-i is selected. This page includes m flash memory cells 106. The flash memory cell 106-a needs to be programmed to store logic “0”. The flash memory cell 106-a is connected to the word line 104-i and the bit line 102-2. A voltage V₁ (about 0 volts) is applied to the bit line 102-2, and a program inhibit voltage V₂ (about 2.5 volts) is applied to other bit lines (102-1, 102-3, . . . 102-m). A programming voltage V_{pgm} (about 20 volts) is applied to the word line 104-i, and a pass voltage Vₚₐₛₛ (about 9 volts) is applied to other word lines. For ease of description, in the example shown in FIG. 4, only one flash memory cell in the selected page needs to be programmed. It should be noted that the number of flash memory cells to be programmed in the selected page is determined according to the data to be stored.

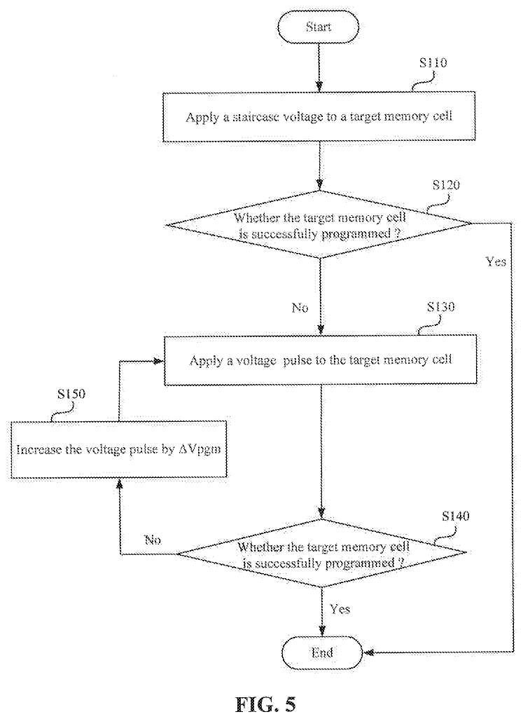

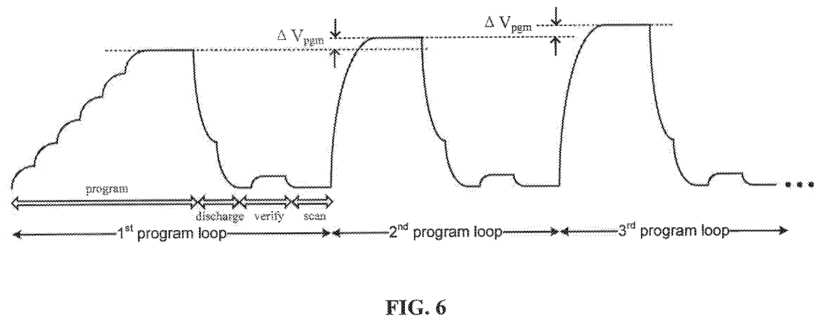

FIG. 5 is flowchart of a programming method for the flash memory according to the present disclosure. The waveform of the programming voltage applied in the programming method is illustrated in FIG. 6. The programming voltage includes a staircase pulse and one or more incremental step pulses after the staircase pulse. As shown in FIG. 5, the programming method includes steps S110 to S150.

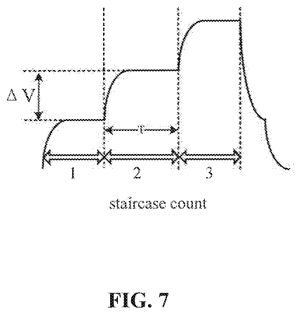

In step S110, a staircase pulse is applied to the word line of a selected page. The staircase pulse increases from a first voltage level to a second voltage level. The staircase pulse is shown in FIG. 7. As shown in FIG. 7, the staircase pulse includes multiple increasing stairs, and may be characterized by: a step size Δ V, the level V0 of the initial stair of the staircase pulse (that is, the first voltage level), the staircase count n, and a time duration T of each stair. The staircase count is, for example, is 6-10 in this embodiment. The step size Δ V, the level V0 of the initial stair of the staircase pulse, the staircase count, and the duration T of each stair may be predetermined in advance. A state machine in the controller may store parameters associated with the step size Δ V, the level V0 of the initial stair of the staircase pulse, the staircase count, and the duration T of each stair.

Table 1 shows the parameters associated with the staircase count. The controller may access the state machine to select the staircase count used in the programming method. For example, if the controller access the state machine with 0011, the controller will generate a staircase pulse with the staircase count being 3.

TABLE 1

| [3] | [2] | [1] | [0] | staircase count n |
|---|---|---|---|---|
| 0 | 0 | 0 | 0 | disable |
| 0 | 0 | 0 | 1 | 1 |
| 0 | 0 | 1 | 0 | 2 |
| 0 | 0 | 1 | 1 | 3 |
| 0 | 1 | 0 | 0 | 4 |
| 0 | 1 | 0 | 1 | 5 |
| 0 | 1 | 1 | 0 | 6 |
| 0 | 1 | 1 | 1 | 7 |
| 1 | 0 | 0 | 0 | 8 |
| 1 | 0 | 0 | 1 | 9 |
| 1 | 0 | 1 | 0 | 10 |
| 1 | 0 | 1 | 1 | 11 |
| 1 | 1 | 0 | 0 | 12 |
| 1 | 1 | 0 | 1 | 13 |
| 1 | 1 | 1 | 0 | 14 |
| 1 | 1 | 1 | 1 | 15 |

The parameters associated with the increased amount of voltage (step size) Δ V are stored in the state machine in table 2.

TABLE 2

| [2] | [1] | [0] | Δ V (V) |
|---|---|---|---|
| 0 | 0 | 0 | 0 |
| 0 | 0 | 1 | 0.1 |
| 0 | 1 | 0 | 0.2 |
| 0 | 1 | 1 | 0.3 |
| 1 | 0 | 0 | 0.4 |
| 1 | 0 | 1 | 0.5 |
| 1 | 1 | 0 | 0.6 |
| 1 | 1 | 1 | 0.7 |

The parameters associated with the duration T of each stair are stored in the state machine as shown in table 3.

TABLE 3

| [2] | [1] | [0] | Staircase time T (us) |
|---|---|---|---|
| 0 | 0 | 0 | 0.1 |
| 0 | 0 | 1 | 0.2 |
| 0 | 1 | 0 | 0.3 |
| 0 | 1 | 1 | 0.4 |
| 1 | 0 | 0 | 0.5 |
| 1 | 0 | 1 | 0.6 |
| 1 | 1 | 0 | 0.7 |
| 1 | 1 | 1 | 0.8 |

As shown in FIG. 6, after the last stair is applied, the level of the staircase pulse (that is, the second voltage level) is equal to V0+(n−1)*Δ V, and then the staircase pulse is withdrawn in a discharge phase.

In step S120, a verify operation is performed to determine whether the floating-gate transistors in the selected page are all successfully programmed. In various embodiments of the present disclosure, the verify operation is a reading operation. The verify operation is performed to determine whether the threshold voltage of the floating-gate transistor reaches a desired level. If the floating-gate transistors in the selected page all store logic “0”, it indicates that the selected page is successfully programed. After the verify operation, the result of the verify operation is stored in an SRAM connected to the controller in a scan phase. If the selected page is successfully programed, the method is ended. If the selected page is not successfully programed, a series of incremental step pulses starting from an initial voltage level and having a predetermined step size Δ V_{pgm} are applied to the word line of the selected page as shown in steps S130 to S150. As shown in FIG. 6, the period in which the staircase pulse is applied is referred to as a program phase, and the program phase, the discharge phase, the verify phase and the scan phase may be collectively referred to the program loop. It should be noted that, step S120 is not necessarily performed. In an alternative embodiment, after the staircase pulse applied to the word line of the selected page is removed, no verify operation is performed, and the series of incremental step pulses are directly applied.

In step S130, a voltage pulse with the initial voltage level (that is, the first one of the series of incremental step pulses) is applied to the word line of the selected page. In an exemplary embodiment, the initial voltage level is equal to V0+(n−1)*Δ V+Δ V_{pgm}. That is, the initial voltage level of the series of incremental step pulses is equal to the second voltage level plus the step size Δ V_{pgm} of the series of incremental step pulses.

When the voltage pulse with the initial voltage level is applied to the word line of the selected page in step S130, a program inhibit voltage of about 2V is applied to the bit line to which the memory cell that has been successfully programed in the step 110 is connected. In this way, the memory cell that has been successfully programed will not be changed.

In step S140, a verify operation is performed to determine whether the floating-gate transistors in the selected page are all successfully programmed. The result of the verify operation is also stored in the controller. If the selected page is successfully programed, the method is ended. If the selected page is not successfully programed, the method proceeds to step S150. The memory cells that are successfully programed are recorded in the scan phase after the verify operation.

In step S150, a next voltage pulse with a level increased by Δ V_{pgm} than the previous voltage pulse is applied to the word line of the selected page. When the next voltage pulse is applied to the word line of the selected page in step S150, the program inhibit voltage of about 2V is applied to the bit lines to which the memory cells that have been successfully programed are connected. In this way, the memory cells that have been successfully programed will not be changed.

After the voltage pulse is applied, the method goes to step 140, that is, a verify operation is performed for step S150 to determine whether the floating-gate transistors in the selected page are all successfully programmed. If the selected page is successfully programed, the method is ended. If the selected page is not successfully programed, the method goes back to step S150, and a yet next voltage pulse with an increased level is applied to the word line of the selected page. When the threshold voltage reaches the desired level (that is, until the floating-gate transistors in the selected page are all successfully programmed), the method ends.

In various embodiments, the step size Δ V_{pgm} may be less than 2V and greater than 0.1V.

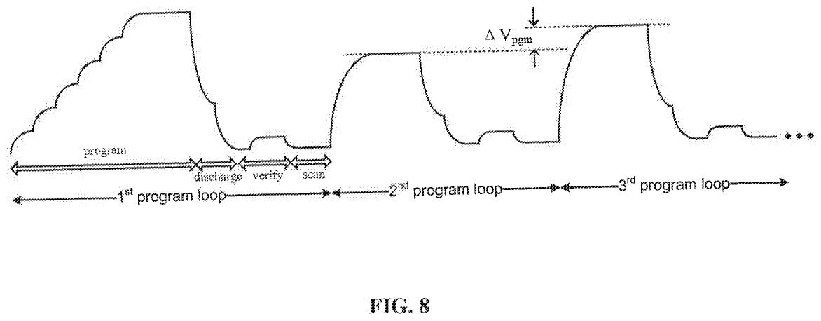

FIG. 8 is a schematic diagram illustrating the waveform of another programming voltage applied in an alternative embodiment. As shown in FIG. 8, the initial voltage level of the series of incremental step pulses is not determined by the level of the last stair of the staircase pulse (the second voltage level), that is, the voltage pulse in step S130 is independent of the staircase voltage in step S110.

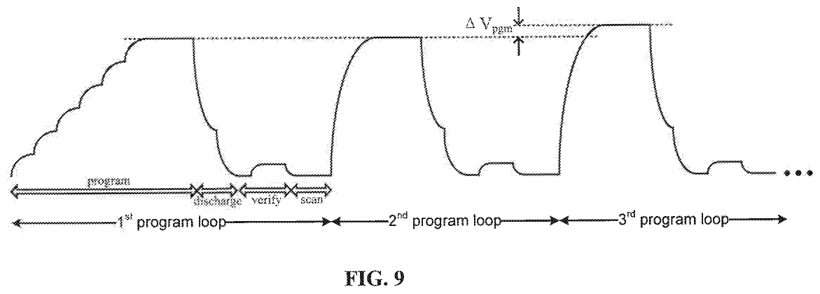

FIG. 9 is a schematic diagram illustrating the waveform of yet another programming voltage applied in an alternative embodiment. As shown in FIG. 9, the initial voltage level of the series of incremental step pulses is equal to the level of the last stair of the staircase pulse (the second voltage level), that is, the level of the voltage pulse in step S130 is equal to the level of the last stair of the staircase voltage in step S110.

It should be noted that the above programming method can be performed by the controller 200 of the flash memory 10.

Further, a computing system is provided by the present disclosure. The computing system includes the flash memory disclosed in any of the above embodiments.

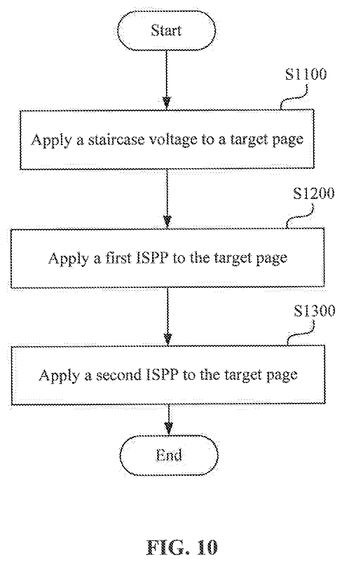

FIG. 10 is a programming method provided by another embodiment of the present disclosure. As shown in FIG. 10, in step S1100, a program voltage pulse is applied to the word line connected to a target memory cell in the memory cell array. The program voltage pulse is a staircase shape and increases from a first voltage level to a second voltage level. In this embodiment, the verify phase and the scan phase are not performed for the program voltage pulse in step S1100 to reduce the programming time.

In step S1200, a series of incremental step pulses are applied to the word line of the selected page, that is a first ISPP is applied. The series of incremental step pulses start from an initial voltage level and having a predetermined step size Δ V_{pgm1}. After the series of incremental step pulses are all applied, the verify phase and the scan phase are performed to determine whether the selected page is successfully programmed. Alternatively, the verify phase and the scan phase are not performed for the series of incremental step pulses.

In step S1300, another series of incremental step pulses are applied to the word line of the selected page, that is a second ISPP is applied. The series of incremental step pulses start from an initial voltage level and having a predetermined step size Δ V_{pgm2}. For each voltage pulse in the second ISPP, the verify phase and the scan phase are performed.

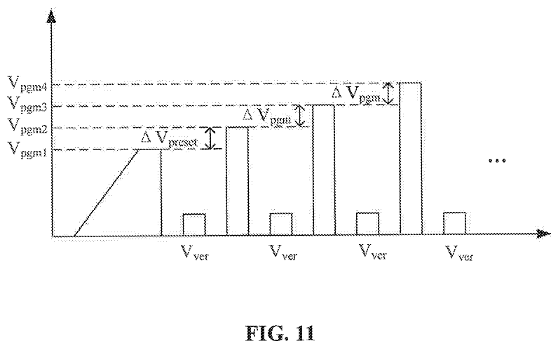

FIG. 11 is a schematic diagram illustrating a programming voltage according to yet another programming method. With reference to FIG. 3 and FIG. 11, in the programming method shown in FIG. 11, a program voltage pulse is applied to the word line of the selected page firstly. The program voltage pulse linearly increases from the first voltage level to the second voltage level V_{pgm1}. The first voltage level may be 0 volts but is not limited to 0 volts. Next, a verify voltage is applied to the word line of the selected page in the verify phase, and whether the selected page is successfully programmed is determined. If it is determined that the selected page is successfully programmed, one or more incremental step voltage pulses (V_{pgm2}, V_{pgm3}, V_{pgm4} . . . ) are applied to the word line, that is an ISPP is performed. The one or more incremental step voltage pulses have a step size Δ V_{pgm}. The initial level V_{pgm2} of the one or more incremental step voltage pulses is equal to a sum of the second voltage level V_{pgm1} and a predetermined value Δ Vₚᵣₑₛₑₜ. In an alternative embodiment, the predetermined value Δ Vₚᵣₑₛₑₜ is equal to the step size Δ V_{pgm}. In another alternative embodiment, the predetermined value Δ Vₚᵣₑₛₑₜ is equal to 0 volts.

In various embodiments, the nonvolatile memory is at least one of a multimedia card (MMC) card, a Secure Digital (SD) card, a micro SD card, a memory stick, an ID card, a PCMCIA card, a chip card, a USB card, a smart card, and a Compact Flash (CF) card.

The nonvolatile memory may be packaged by a Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

While exemplary embodiments are described above, it is not intended that these embodiments describe all possible forms encompassed by the claims. The words used in the specification are words of description rather than limitation, and it is understood that various changes may be made without departing from the spirit and scope of the disclosure and claims. As previously described, the features of various embodiments may be combined to form further embodiments of the invention that may not be explicitly described or illustrated. While various embodiments may have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to: cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

1. A nonvolatile memory, comprising:
word lines;
bit lines;
a memory cell array addressed through the word lines and bit lines; and
a controller,
wherein the controller is configured to: apply one program voltage pulse to the word line connected to a target memory cell in the memory cell array, and then apply one or more incremental step voltage pulses to the word line connected to the target memory cell in the memory cell array,
wherein the one program voltage pulse increases from a first voltage level to a second voltage level; and
wherein the one or more incremental step voltage pulses start from an initial voltage level and have a predetermined step size, and the initial voltage level is equal to the second voltage level.

2. (canceled)

3. (canceled)

4. (canceled)

5. (canceled)

6. The nonvolatile memory according to claim 1, wherein the one program voltage pulse linearly increases from the first voltage level to the second voltage level.

7. The nonvolatile memory according to claim 1, wherein the one program voltage pulse is in a staircase shape.

8. The nonvolatile memory according to claim 7, wherein a time duration of each stair of the one program voltage pulse is less than or equal to 0.8 us.

9. The nonvolatile memory according to claim 7, wherein a step size of the one program voltage pulse is less than or equal to 0.7 V.

10. The nonvolatile memory according to claim 7, wherein time durations of stairs of the one program voltage pulse are consecutive in time.

11. The nonvolatile memory according to claim 1 is a NAND flash memory.

12. A computing system, comprising: a nonvolatile memory, wherein the nonvolatile memory comprises: word lines, bit lines, a memory cell array addressed through the word lines and bit lines; and a controller,
wherein the controller is configured to: apply one program voltage pulse to the word line connected to a target memory cell in the memory cell array, and then apply one or more incremental step voltage pulses to the word line connected to the target memory cell in the memory cell array,
wherein the one program voltage pulse increases from a first voltage level to a second voltage level; and
wherein the one or more incremental step voltage pulses start from an initial voltage level and have a predetermined step size, and the initial voltage level is equal to the second voltage level.

13. A programming method of a nonvolatile memory, comprising:
applying one program voltage pulse to a word line connected to a target memory cell, and then applying one or more incremental step voltage pulses to the word line connected to the target memory cell,
wherein the one program voltage pulse increases from a first voltage level to a second voltage level; and
wherein the one or more incremental step voltage pulses start from an initial voltage level and have a predetermined step size, and the initial voltage level is equal to the second voltage level.

14. (canceled)

15. (canceled)

16. (canceled)

17. (canceled)

18. The programming method according to claim 13, wherein the one program voltage pulse linearly increases from the first voltage level to the second voltage level.

19. The programming method according to claim 13, wherein the one program voltage pulse is in a staircase shape.

20. The programming method according to claim 19, wherein time durations of stairs of the one program voltage pulse are consecutive in time.
